(19) United States
(12) Patent Application Publication
(10) Pub. No.: US 2012/0326288 A1
(43) Pub. Date: Dec. 27, 2012

(54) METHOD OF ASSEMBLING SEMICONDUCTOR DEVICE

(75) Inventors: Meiquan Huang, Tianjin (CN); Hejin Liu, Tianjin (CN); Zhijie Wang, Tianjin (CN); Dehong Ye, Tianjin (CN); Hanmin Zhang, Tianjin (CN)

(73) Assignee: FREESCALE SEMICONDUCTOR, INC, Austin, TX (US)

(21) Appl. No.: 13/489,462

(22) Filed: Jun. 6, 2012

(30) Foreign Application Priority Data
Jun. 23, 2011 (CN) 201110169920.2

(51) Int. Cl. H01L 21/56; H01L 23/495

(52) U.S. Cl. 257/676; 438/123; 257/E23.052; 257/E21.502

(57) ABSTRACT

A method of assembling a semiconductor device includes providing a conductive lead frame panel and selectively half-etching a top side of the lead frame panel to provide a pin pads. A flip chip die is attached and electrically connected to the pin pads and then the lead frame panel and die are encapsulated with molding compound. A second selective half etching step is performed on a backside of the lead frame panel to form a plurality of separate input/output pins. The side walls of each input/output pin include arcuate surfaces in cross-section.

### BACKGROUND OF THE INVENTION

The present invention relates to semiconductor packaging and more particularly to a method of assembling a semiconductor device using a half etch process.

In a conventional flip-chip (FC) Quad Flat No Lead (QFN) package electrical connections between the die and lead frame are usually made by way of interconnect pads on the periphery of the associated die. However, for many die, the interconnect pads are situated in a central portion of the die including interconnect pads for power and ground connections. Such die cannot be mounted in a conventional FC QFN package unless the die pad layout is changed and some peripheral die pads are dedicated to ground or power connections.

It is desirable to provide a lead frame based FC QFN package having a relatively high density of input/output (I/O) pins distributed in an array on a bottom surface of the QFN package including central and peripheral portions relative to the die.

Conventional array QFN packages use saw blades to singulate pins from those of adjacent packages and with the die flag. The singulation process has a half-cutting issue because over cutting damages the package while under cutting cannot isolate the pins completely.

It is desirable to adopt a process for manufacturing FC QFN packages that can avoid the half-cutting issue.

### BRIEF DESCRIPTION OF THE DRAWINGS

The following detailed description of a preferred embodiment of the invention will be better understood when read in conjunction with the appended drawings. The present invention is illustrated by way of example and is not limited by the accompanying figures in which like references indicate similar elements. It is to be understood that the drawings are not to scale and have been simplified for ease of understanding the invention.

FIGS. 1A and 1B show cross-section and underside views of a Chip Scale Package (CSP) FC array QFN package;

FIG. 2A illustrates steps of a process for assembling a CSP FC array QFN package in accordance with an embodiment of the present invention;

FIG. 2B shows details of pin pads with arcuate side walls;

FIGS. 3A and 3B show cross-section and underside views of a non-CSP (standard size) FC array QFN package;

FIG. 4 illustrates steps of a process for assembling a non-CSP FC array QFN package in accordance with an embodiment of the present invention;

FIG. 5 show details of selective plating (step 40) in FIG. 4; and

FIG. 6 shows details of lead frame topside half etch (step 41) in FIG. 4.

### DETAILED DESCRIPTION OF THE INVENTION

According to the present invention a process for assembling a semiconductor device includes providing a conductive lead frame panel; selectively half etching a top side of said lead frame panel to provide a plurality of pin pads; attaching a flip chip die to said pin pads; encapsulating said lead frame panel and die with molding compound; and selectively half etching a backside of said lead frame panel to form a plurality of separate input/output pins.

The lead frame panel may comprise copper. The semiconductor device may comprise a chip size package (CSP). Alternatively the semiconductor device may comprise a non-CSP or standard size package. The semiconductor device may comprise a lead frame based Quad Flat No Lead (QFN) package. The side walls of each input/output pin may include one or more arcuate or arched surfaces in cross-section. The plurality of input/output pins may be arranged in a two dimensional array on a bottom surface of the semiconductor device. The step of selectively half etching may include selective plating with an alloy such as tin/lead or nickel/palladium. The step of attaching a flip chip die may include applying solder bumps or balls to the pin pads and subjecting the device to an elevated temperature to reflow or melt the solder bumps or balls.

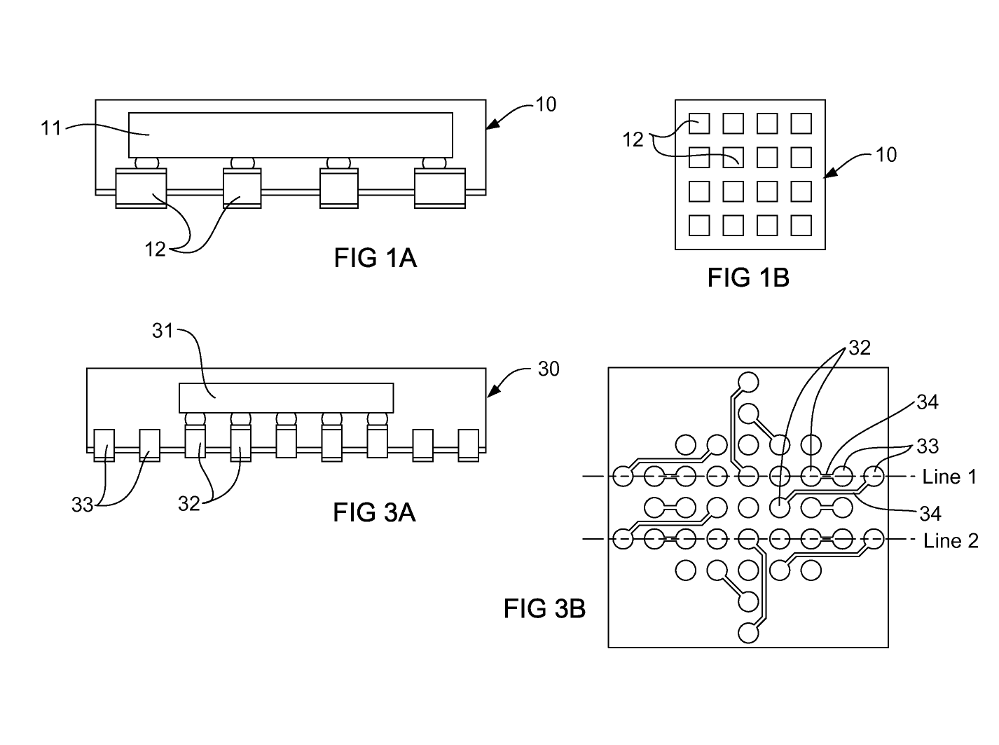

FIG. 1A is a cross-sectional view of a CSP FC array QFN package 10 that is typically not much larger (less than X1.2) than the size of a die 11 within the package 10.

FIG. 1B is a bottom view of the QFN package 10 including a plurality of I/O pins 12 distributed below the die 11. The I/O pins 12 are distributed in a two dimensional array on a bottom surface of the QFN package 10 including central and peripheral positions relative to the die 11.

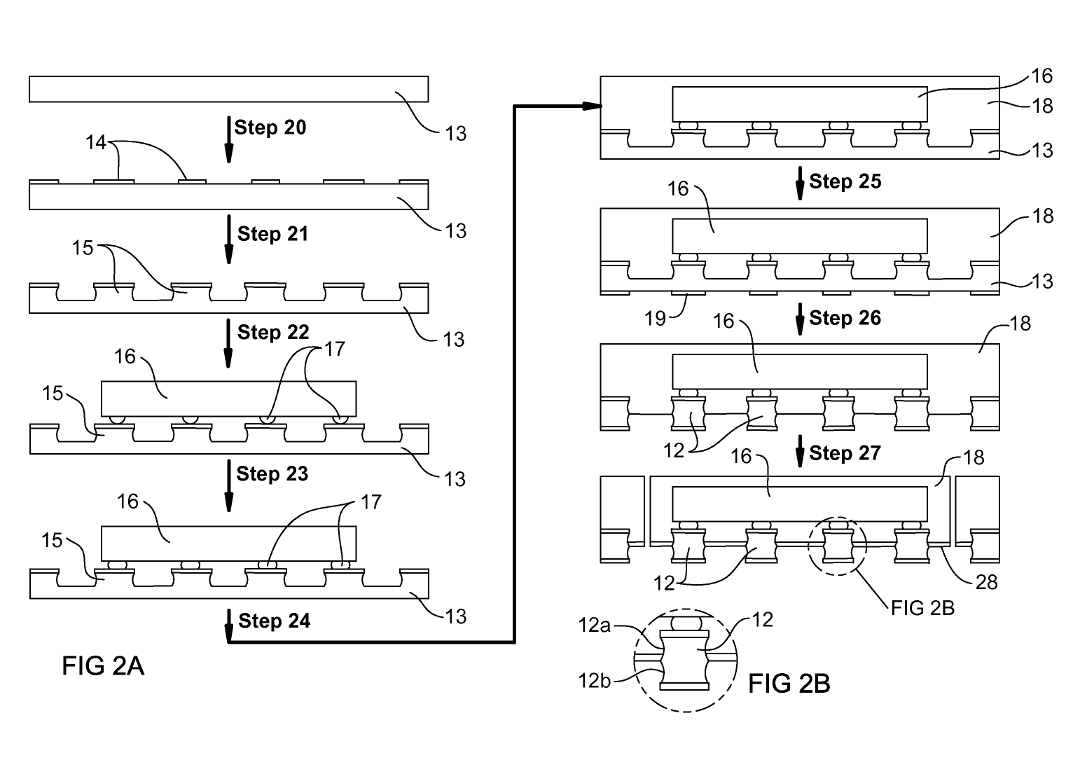

A process for assembling the CSP FC array QFN package 10 is described below with reference to the process flow diagram in FIG. 2A. The assembly process starts with a copper plate 13 that is used to form a lead frame of the QFN package. The copper plate 13 is masked and selectively plated on a top side with an alloy such as tin/lead or nickel/palladium in step 20. Selective plating is applied to target areas 14 on the copper plate 13 and no plating is applied to other areas. One method for performing the selective plating step 20 is described below with reference to FIG. 5.

Following the selective plating step 20, the copper plate 13 (lead frame) is selectively etched in step 21 on the top side to approximately half of the original thickness of the copper plate 13. The half etch step 21 may be performed in any suitable manner and by any suitable means (e.g. using acid) as is known in the industry. The half etch step 21 on the top side of the copper plate 13 produces a plurality of joined pin pads 15 in relief above the surface of the lead frame.

Following the half etch step 21 a flip chip die 16 is attached to the plurality of pin pads 15 in steps 22 and 23. In step 22, solder is applied to the pin pads 15 to form solder bumps or balls 17. The die 16 is then positioned over the lead frame with die pads on the die 16 aligned with the solder bumps or balls 17. In step 23, a reflow process is performed in which the solder balls 17 are subjected to an elevated temperature to melt the solder balls 17 and the plurality of pin pads 15 so that respective die pads on the die 16 are attached and electrically connected to the pin pads 15 by way of the solder balls 17.

The die attach steps 22 and 23 are followed by an encapsulation step 24 that encapsulates the copper plate (lead frame) 13 and die 16 with a molding compound 18.

The encapsulation step 24 is followed by a second masking and selective plating step 25 on the backside of the copper plate (lead frame) 13, in which a second selective plating is applied to target areas 19 of the copper plate 13 and no plating is applied to other areas. The second plating step 25 is similar to the first plating step 20, which is described in more detail with reference to FIG. 5.

Following the selective plating step 25, the backside of the copper plate (lead frame) 13 is selectively etched (removed) in step 26 to approximately half of the original thickness of the copper plate 13. The half etch step 26 may be performed in any suitable manner and by any suitable means (e.g. acid) as is known in the industry. The half etch step 26 on the backside of the copper plate 13 produces a plurality of separated pins 12 that correspond to I/O pins 12 in FIG. 1B.

One benefit of the half etching steps 21 and 26 is that the side walls of the I/O pins 12 are not etched flat or vertical. Rather as shown in FIG. 2B, the etching process forms side walls of I/O pins 12 with arcuate or arched surfaces 12a and 12b in cross-section that provide a better key or mold lock with the molding compound 18 and for integration with solder on a circuit board. For example, the arched surfaces 12a associated with the upper half of the pins 12 provide a key for integration with the molding compound 18, and arched surfaces 12b associated with the lower half of the pins 12 provide a key for integration with solder on a circuit board (not shown).

Following the half etch step 26 the semiconductor panel is singulated, such as with a saw, in step 27, into individual QFN semiconductor devices. The singulation step 27 is performed by means of a cutting tool as is known in the art. The singulation step 27 may be preceded by an additional (optional) step in which a solder mask or solder resist is applied to target areas 28 on the underside of the copper plate 13 to reduce the risk of shorting of pins 12 during a surface mount technology (SMT) process. The step of applying solder mask or solder resist to target areas 28 may be performed in any suitable manner and by any suitable means, such as selective etching, as is known in the industry. The target areas 28 are the areas between the I/O pins 12.

FIG. 3A is a cross-sectional view of a non-CSP (standard size) FC array QFN package 30 that is typically larger than the size of the associated die 31.

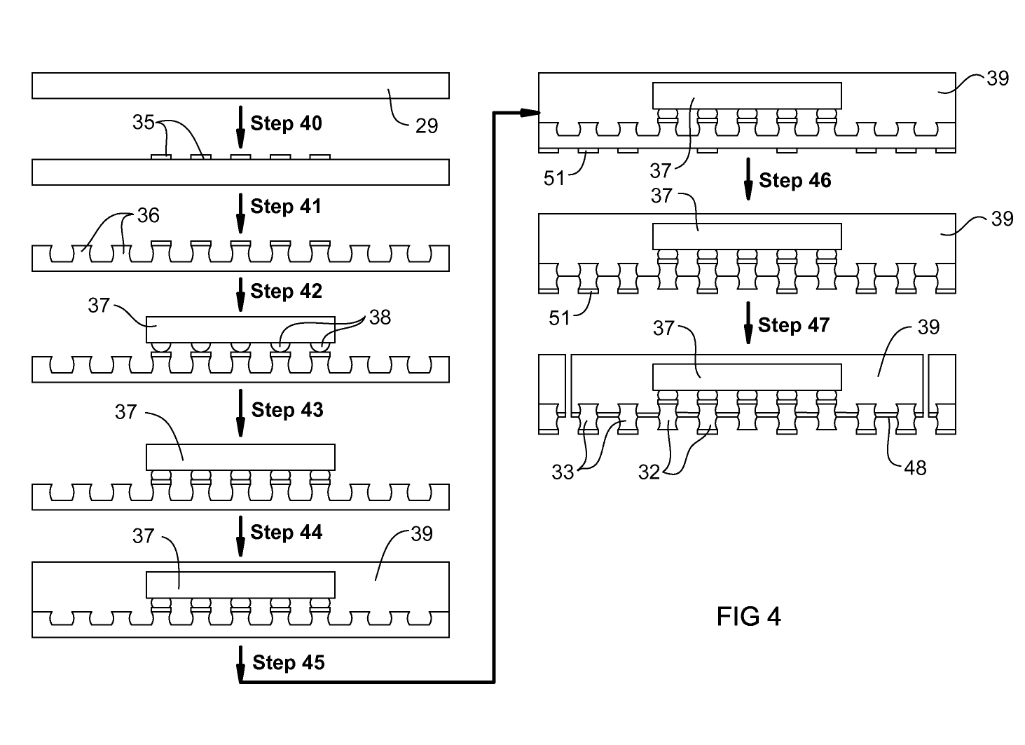

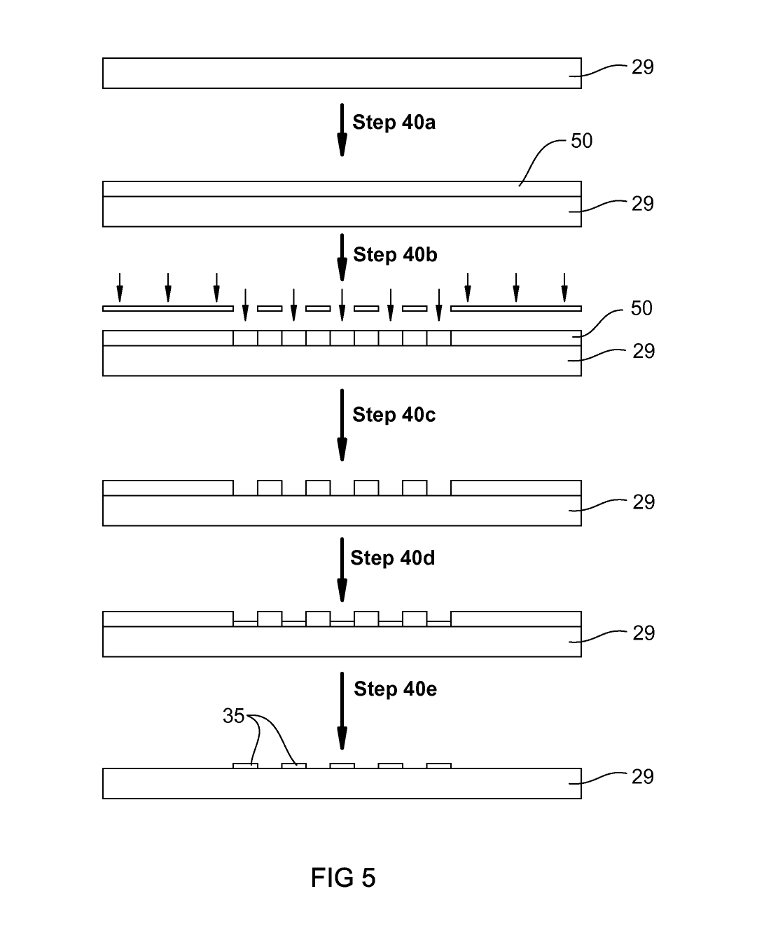

FIG. 3B is a bottom plan view of the QFN package 30 including a plurality of inner and outer I/O pins 32, 33. The locations of the inner I/O pins 32 correspond to positions of respective pads on the die 31. The outer I/O pins 33 are provided to facilitate relocation or redistribution from inner I/O pins 32 via tracks 34. The broken line 1 (or 2) in FIG. 3B corresponds to cross-sectional views shown in FIG. 4.

A method of assembling the non-CSP FC array QFN package 30 is described below with reference to the process flow diagram in FIG. 4. The manufacturing process starts with a copper plate 29 that will form the lead frame of the QFN package 30. The copper plate 29 is masked and selectively plated on the top side with an alloy such as tin/lead or nickel/palladium in step 40. Selective plating is applied to target areas 35 on the copper plate 29 and no plating is applied to other areas. One method for performing the selective plating step 40 is described below with reference to FIG. 5.

Following the selective plating step 40, the copper plate 29 (lead frame) is selectively etched (removed) in step 41 on the top side to approximately half of the thickness of the copper plate 40. The half etch step 41 may be performed in any suitable manner and by any suitable means (e.g., using acid) as is known in the industry. The half etch step 41 on the top side of the copper plate 29 produces a plurality of joined pin pads 36 in relief above the surface of the copper plate (lead frame) 29.

Following half etch step 41, a flip chip die 37 is attached to the plurality of pin pads 36 in steps 42 and 43. In step 42, solder 38 is applied to the pin pads 36 in the form of bumps or balls. A die 37 is then positioned over the copper plate (lead frame) 29 with die pads of the die 37 aligned with the solder bumps or balls. The solder 38 is subjected to an elevated temperature in step 43 to cause the solder 38 to reflow or melt so that the plurality of pin pads 36 are attached and electrically connected to respective die pads on the die 37.

The die attach steps 42 and 43 are followed by an encapsulation step 44 that encapsulates the copper plate 29 and the die 37 with a molding compound 39.

The encapsulation step 44 is followed by a second masking and selective plating step 45 on the backside of the copper plate (lead frame) 29. The second selective plating is applied to target areas 51 of the copper plate 29 and no plating is applied to other areas. The second plating step 45 is similar to the first plating step 40, which is described in greater detail with reference to FIG. 5.

Following the selective plating step 45 the backside of the copper plate (lead frame) 29 is selectively etched (removed) in step 46 to approximately half of the original thickness of the copper plate 29. The half etch step 46 may be performed in any suitable manner and by any suitable means (e.g., using acid) as is known in the industry. The half etch step 46 on the backside of the copper plate 29 produces a plurality of separated inner and outer I/O pins 32, 33 that correspond to I/O pins 32, 33 in FIG. 3B.

One benefit of the two half etching steps 41 and 46 is that the side walls of the I/O pins 32, 33 are not etched flat or vertical. Rather as shown in FIG. 2B the etching process forms side walls of the I/O pins 32, 33 with arcuate or arched surfaces in cross-section comparable to surfaces 12a and 12b (FIG. 2B) that provide a good key or mold lock with the molding compound 39 and for integration with solder on a circuit board (not shown).

Following the half etch step 46 the copper plate 29 is singulated in step 47 into individual QFN semiconductor devices. The singulation step 47 preferably is performed by means of a cutting tool such as a saw as is known in the art. The singulation step 47 may be preceded by an additional (optional) step in which a solder mask or solder resist is applied to target areas 48 on the underside of the copper plate 29 to reduce the risk of shorting of the pins 32, 33 during a surface mount technology (SMT) process. The step of applying solder mask or solder resist to target areas 48 may be performed in any suitable manner and by any suitable means such as selective etching, as is known in the industry. The target areas 48 are the areas between the I/O pins 32, 33.

FIG. 5 illustrates sub-steps of the selective plating step 40 of FIG. 4. Step 40 includes sub-step 40a in which a photo resist layer 50 is applied over the copper plate 29 in any suitable manner and by any suitable means. This is followed by sub-step 40b in which the photo resist layer 50 is selectively (by means of masks or the like) exposed to ultraviolet light and sub-step 40c in which the selectively exposed layer 50 is developed to remove the selectively exposed (target) areas of the layer 50. In one embodiment, the target areas of the copper plate 29 that are selectively exposed are plated in sub-step 40d with an alloy such as tin/lead, nickel/palladium or the like. Finally the remaining portions of the photo resist layer 50 are removed in sub-step 40e to leave selectively plated areas 35 as described with reference to FIG. 4.

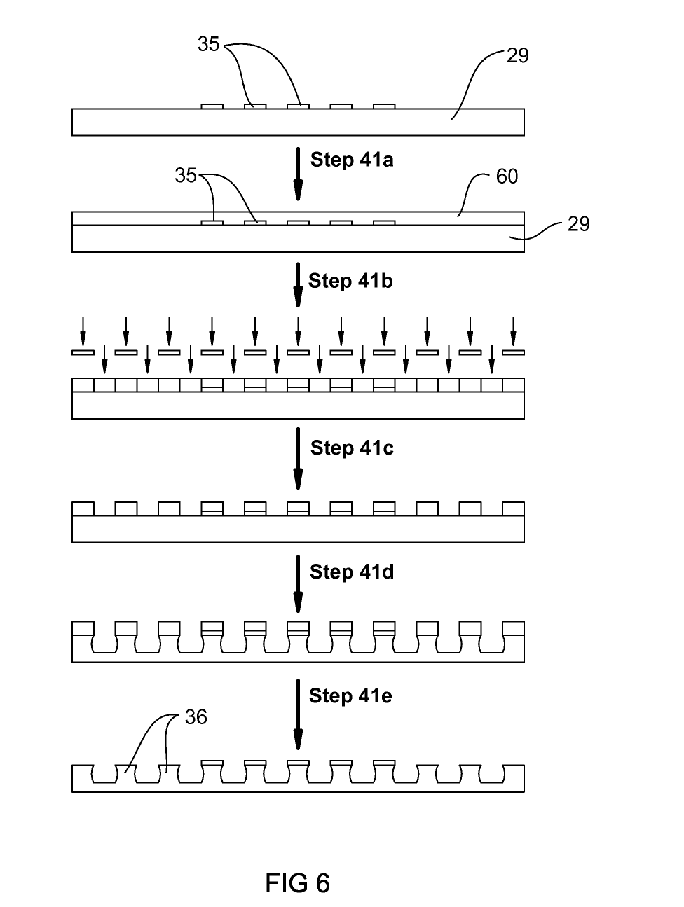

FIG. 6 shows sub-steps of the top side half etch step 41 of FIG. 4. Step 41 includes sub-step 41a where a photo resist layer 60 is applied over the copper plate 29 including the areas 35 that were selectively plated in step 40, in any suitable manner and by any suitable means. This is followed by sub-step 41b where the photo resist layer 60 is selectively (by means of masks or the like) exposed to ultraviolet light and sub-step 41c where the selectively exposed layer photo resist layer 60 is developed to remove the selectively exposed (target) areas of the layer 60. The target areas exclude the plated areas 35 that were selectively plated in step 40. The target areas of the copper plate 29 are etched in any suitable manner and by any suitable means (e.g. using acid) to approximately half the thickness of the copper plate 29. Finally the remaining portions of the photo resist layer 60 are removed in sub-step 41e to leave a plurality of joined pin pads 36 as described above with reference to FIG. 4.

The QFN package of the present invention includes a metal (e.g., copper) lead frame based package and has good thermal conductive performance.

The QFN package of the present invention also has relatively high density pin count compared to a standard QFN package. Being a FC QFN package, wire bonding is avoided enabling short signal paths and less signal attenuation. Because pin isolation is achieved by two half etching steps instead of saw cutting, the half cutting issue described above is neatly avoided. Finally half etching has an advantage in that side walls of the I/O pins are arcuate or arched in cross-section to provide a better key with the material of the molding compound as well as improved integration with solder on a circuit board.

As is evident from the foregoing discussion, the present invention provides a method of assembling a semiconductor device using a half etch process. While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention as defined in the claims.

1. A method of assembling a semiconductor device, comprising:
providing a conductive lead frame panel;
selectively half etching a top side of said lead frame panel to provide a plurality of pin pads;
attaching and electrically connecting a flip chip die to said pin pads;
encapsulating said lead frame panel and die with molding compound; and
selectively half etching a backside of said lead frame panel to form a plurality of separate input/output pins.

2. The method of assembling a semiconductor device of claim 1, wherein said lead frame panel comprises a copper plate.

3. The method of assembling a semiconductor device of claim 1, wherein said semiconductor device comprises a chip size package (CSP).

4. The method of assembling a semiconductor device of claim 1, wherein said semiconductor device comprises a Quad Flat No Lead (QFN) lead frame package.

5. The method of assembling a semiconductor device of claim 1, wherein side walls of each input/output pin include one or more arcuate surfaces in cross-section.

6. The method of assembling a semiconductor device of claim 1, wherein said plurality of input/output pins are arranged in a two dimensional array on a bottom surface of said semiconductor device.

7. The method of assembling a semiconductor device of claim 1, wherein said step of selectively half etching includes selective plating with an alloy.

8. The method of assembling a semiconductor device of claim 7, wherein the alloy comprises one of tin/lead and nickel/palladium.

9. The method of assembling a semiconductor device of claim 1, wherein said step of attaching a flip chip die includes applying solder bumps to said pin pads and subjecting the device to an elevated temperature to reflow the solder bumps.

10. A semiconductor device produced by the method of claim 1.
